(19) United States
(12) Patent Application Publication
(10) Pub. No.: US 2006/0048968 A1
(43) Pub. Date: Mar. 9, 2006

(54) Construction for DC to AC power inverter

(76) Inventor: Wei-Kuang Chen, Pa Teh City (TW)

Correspondence Address: RAYMOND Y. CHAN, 108 N. YNEZ AVE., SUITE 128, MONTEREY PARK, CA, 91754, US

(21) Appl. No.: 10/933,860

(22) Filed: Sep. 3, 2004

(51) Int. Cl. H05K 1/09

(52) U.S. Cl. 174/257; 174/267

(57) ABSTRACT

A construction for DC to AC power inverter includes a circuit board and at least a conductive member. The soldered surface of the circuit board where larger amount of current passes through is inserted with the conductive member. The conductive member provides a contour can be changed in accordance with the shape of the circuit board and the periphery thereof is joined with several inserting pins so that the conductive member can be inversely hooked to the circuit board. Further, the conductive member can adhesively attached to the circuit board tightly by way of operation of tin soldering with the tin furnace. Hence, the conductive member can facially contact with the circuit board to enhance capability of the copper foil on the circuit board to endure the current with lower fabricating cost and promoted utilization efficiency. Besides, obstruction of other electronic parts can be avoided so as to facilitate fabrication process and strengthen market competitive power.

### BACKGROUND OF THE INVENTION

1. Field of the Invention

The present invention is related to a construction for DC to AC power inverter, which can increase current passing through the circuit board largely, lower fabrication cost and promote circuit efficiency.

2. Brief Description of Related Art

Due to technology progressing rapidly, various home electric appliances are brought forth the new through the old and the functions thereof are enhanced greatly. It is an important step that a circuit board is used to operate and control the home electric appliances respectively. Referring to FIGS. 1 and 2, a circuit board of a conventional inverter is illustrated. The circuit board 10 provides a copper foil with a thickness of merely 0.035˜0.07 mm so that the copper foil canendure 0.35 Ampere current only. In order to increase current amount passing through the copper foil effectively for offering various electronic parts, a way currently used is that a copper bank 12 is inserted to the surfaces 11 of the parts on the circuit board 10 and the inserting pins 121 on the copper bank 12 are fixedly attached to the circuit board 10 by way of tin soldering. Hence, the current passing through the circuit board can be increased largely and the capability of the circuit board can be enhanced effectively. However, the copper bank 12 is inserted to the surfaces 11 for the electronic parts and it is hard to reach the expected conductive point because of obstruction of other electronic parts 13. Further, the inserting pins on the copper bank 13 is point contact with the circuit board 10 for the current passing through and it is very easy to result in the current concentrating at the inserting pins 121 to occur a phenomenon of heat loss and voltage drop, which is very unfavorable for high frequency circuit with large amount of current, such that the effect thereof is affected significantly.

### SUMARY OF THE INVENTION

Accordingly, an object of the present invention is to provide a construction for DC to AC power inverter, which is capable of increasing the current passing through the circuit board largely.

Another object of the present invention is to provide a construction for DC to AC power inverter, which can lower cost and promote utilization efficiency largely.

A further object of the present invention is to provide a construction for DC to AC power inverter, which has a simple structure for being fabricated easily.

To reach the preceding object, the construction for DC to AC power inverter according to the present invention includes a circuit board and a conductive member. The conductive member provides a contour can be changed in accordance with the shape of the circuit board and the periphery thereof is joined with several inserting pins and the inserting pins are integrally made as a single piece. The circuit board where larger amount of current passes through is provided with holes corresponding to the inserting pins so that the conductive member can be adhesively attached to the soldered surface of the circuit board tightly via the holes by way of operation of tin soldering with the tin furnace. Hence, the conductive member can facially contact with the circuit board to enhance capability of the copper foil on the circuit board enduring the current from tens times to hundreds times and lower fabricating cost and promote utilization efficiency. Besides, obstruction of other electronic parts can be avoided so as to facilitate fabrication process and strengthen market competitive power.

### BRIEF DESCRIPTION OF THE DRAWINGS

The detail structure, the applied principle, the function and the effectiveness of the present invention can be more fully understood with reference to the following description and accompanying drawings, in which:

FIG. 1 is an exploded perspective view of the conventional inverter circuit board;

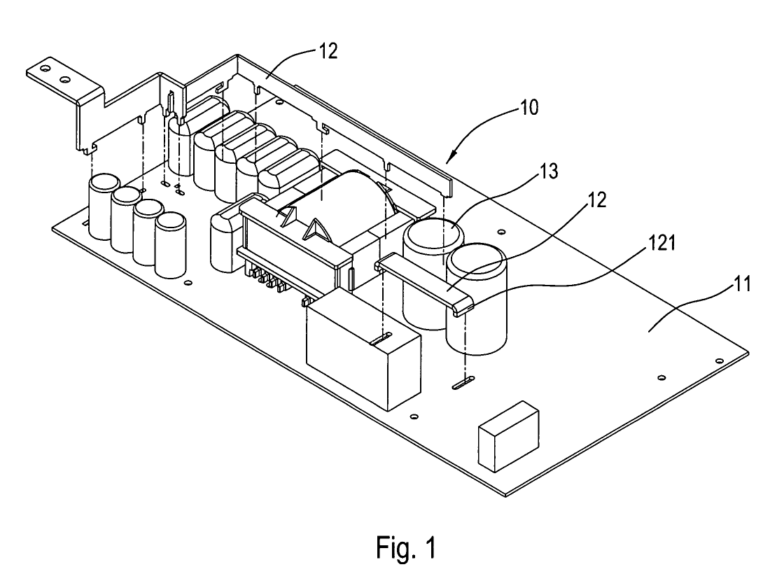

FIG. 2 is a perspective view of the conventional inverter circuit board;

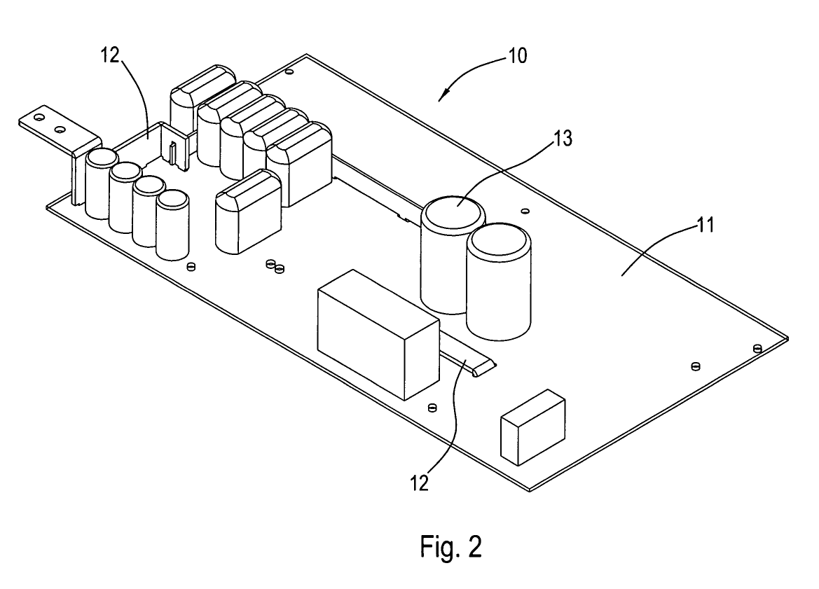

FIG. 3 is an exploded perspective view of an inverter circuit board according to the present invention;

FIG. 4 is a perspective view of the inverter circuit board shown in FIG. 3; and

FIG. 5 is a bottom view of the inverter circuit board according to the present invention;

### DETAILED DESCRIPTION OF THE INVENTION

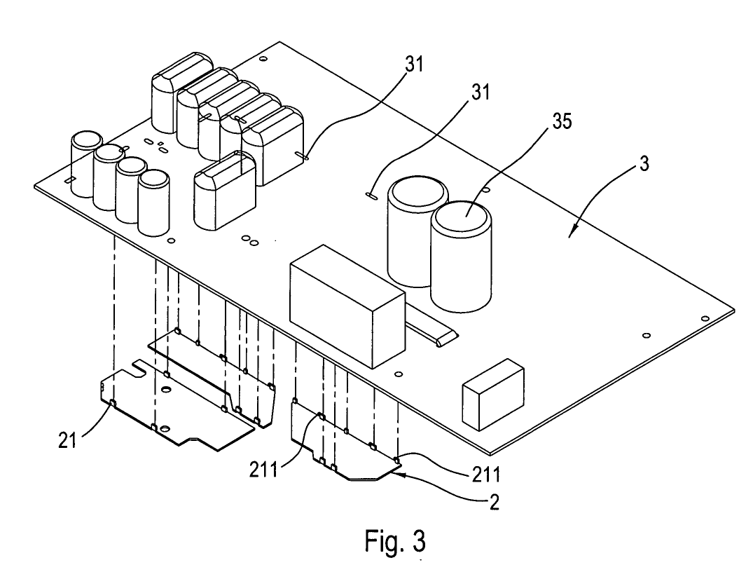

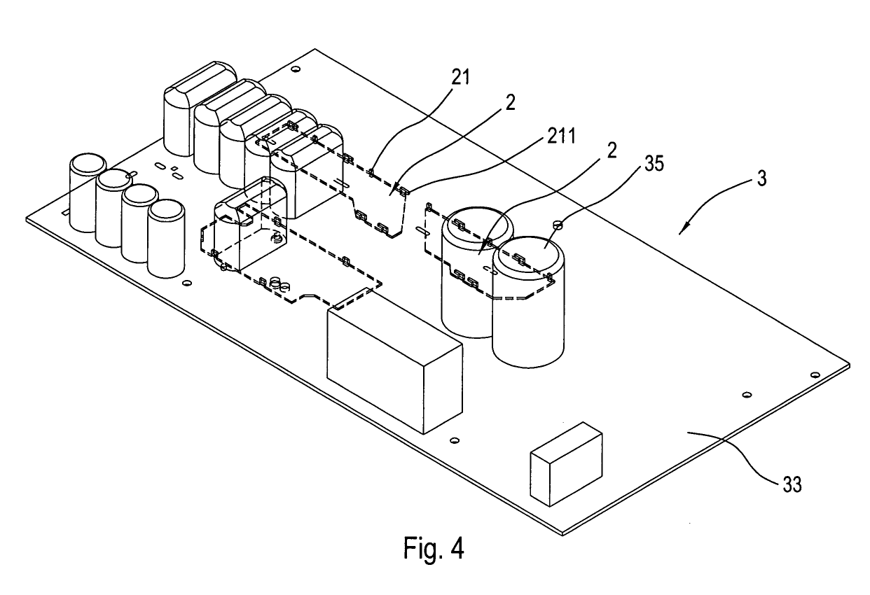

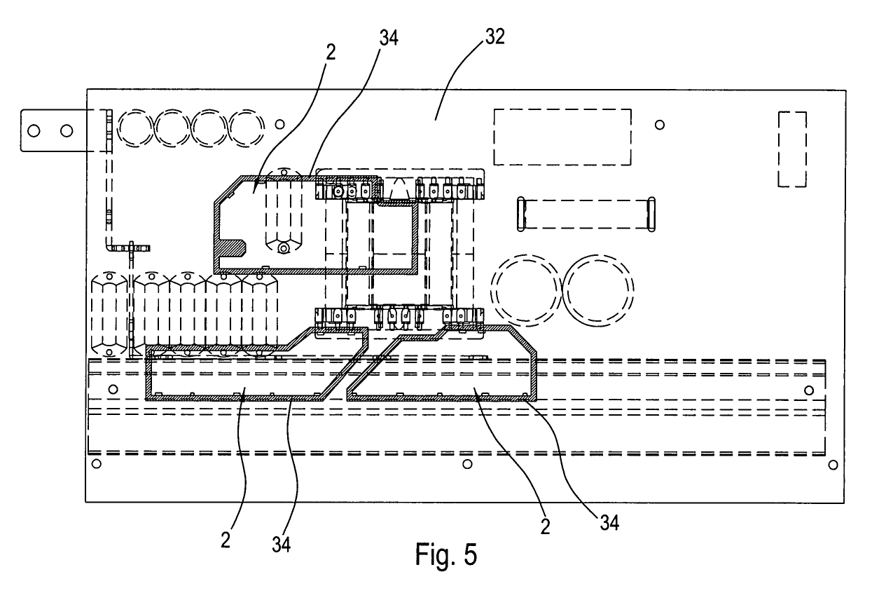

Referring to FIGS. 3 to 5, an inverter circuit board for DC to AC power according to the present invention basically includes at least a conductive member 2 and a circuit board 3. In order to match the circuit boards 3 in different shapes, the contour of the conductive member 2 can be suitably arranged for different situations. The conductive member 2 has several inserting pins 21 surrounding the periphery thereof and each of the inserting pins 21 extends outward an engaging end 211. The conductive member 2 and the inserting pins 21 are integrally made of copper. The circuit board 3 provides fitting holes 31 at areas being passed through with larger current and the holes correspond to the inserting pins 21 so that the inserting pins 21 can engage with the circuit board 3 by way of the engaging ends 211 passing through the fitting holes 31 and reaching the soldered surface 32. In the meantime, the inserting pins 21 of the conductive member 2 can expose at surfaces of electronic parts 33 to be fixedly attached to the soldered surface 32 by way of soldering treatment 34 with the tin furnace. In this way, the conductive member 2 can facially contact with the circuit board 3 and the copper foil on the circuit board 3 can endure much more current passing through the circuit board 3, the fabrication cost of the entire circuit board can be lowered largely and the utilization efficiency of circuit board can be enhanced greatly. In addition, obstruction of other electronic parts 35 can be avoided so as to facilitate the fabrication process and to increase market competitive power and practicality.

It is appreciated that the construction for DC to AC power inverter according to the present invention has the following advantages:

The conductive member is inserted to the soldered surface and is adhesively attached to the circuit board by way of tin soldering so that it can enhance circuit efficiency, reduce heat loss and lower skin-effect loss resulting from high frequency.

While the invention has been described with referencing to the preferred embodiments thereof, it is to be understood that modifications or variations may be easily made without departing from the spirit of this invention, which is defined by the appended claims.

1-5. (canceled)

6. A circuit board assembly for a DC to AC power inverter comprising:
a circuit board having a soldered surface and an opposed component surface for a plurality of electronic parts mounting thereon, wherein a copper foil is provided on said soldered surface of said circuit board for electrically connecting with said electronic parts, wherein said circuit board further has a plurality of fitting holes formed on said circuit board to communicate said soldered surface of said circuit board to said component surface thereof, wherein said fitting holes are located in vicinity of a predetermined high-current area of said circuit board for a relatively larger current passing through said copper foil; and
at least a conductive member comprising a plurality of inserting pins spacedly extending along a periphery of said conductive member, wherein said inserting pins are slidaby inserted into said fitting holes respectively to securely overlap said conductive member on said soldered surface of said circuit board at said high-current area such that said conductive member allow said relatively larger current passing though at said high-current area of said copper foil of said circuit board so as to enhance an endurance of said high-current area of said copper foil of said circuit board.

7. The circuit board assembly, as recited in claim 6, wherein each of said inserting pins has an engaging end protruded from said component surface of said circuit board such that when said conductive member is mounted on said soldered surface of said circuit board to electrically connect with said copper foil, said circuit board maximizes an utilizing area of said component surface for said electronic parts to be affixed thereon.

8. The circuit board assembly, as recited in claim 7, wherein said conductive member is tin-soldering on said soldered surface of said circuit board to enlarge a conductive contacting surface therebetween to electrically connect said conductive member with said copper foil on said soldered surface of said circuit.

9. The circuit board assembly, as recited in claim 6, wherein said inserting pins are integrally extended from said conductive member to align with said fitting holes of said circuit board respectively.

10. The circuit board assembly, as recited in claim 7, wherein said inserting pins are integrally extended from said conductive member to align with said fitting holes of said circuit board respectively.

11. The circuit board assembly, as recited in claim 8, wherein said inserting pins are integrally extended from said conductive member to align with said fitting holes of said circuit board respectively.

12. The circuit board assembly, as recited in claim 6, wherein said conductive member is made of copper.

13. The circuit board assembly, as recited in claim 7, wherein said conductive member is made of copper.

13. The circuit board assembly, as recited in claim 8, wherein said conductive member is made of copper.

14. The circuit board assembly, as recited in claim 9, wherein said conductive member is made of copper.

15. The circuit board assembly, as recited in claim 10, wherein said conductive member is made of copper.

16. The circuit board assembly, as recited in claim 11, wherein said conductive member is made of copper.
